(19) United States
(12) Patent Application Publication
(10) Pub. No.: US 2013/0313002 A1
(43) Pub. Date: Nov. 28, 2013

(54) MULTILAYER PRINTED CIRCUIT BOARD AND METHOD FOR MANUFACTURING SAME

(71) Applicant: SHIH-PING HSU, Tayuan (TW)

(72) Inventor: SHIH-PING HSU, Tayuan (TW)

(73) Assignee: ZHEN DING TECHNOLOGY CO., LTD., Tayuan (TW)

(21) Appl. No.: 13/563,739

(22) Filed: Aug. 1, 2012

(30) Foreign Application Priority Data
May 28, 2012 (TW) 101118932

(51) Int. Cl. H05K 1/03; H05K 3/46

(52) U.S. Cl. 174/251; 156/182; 228/176

(57) ABSTRACT

A method for manufacturing a multilayer printed circuit board includes the step as follows: providing a glass wiring substrate, the glass wiring substrate comprising a first electrically conductive pattern, a glass base, and a second electrically conductive pattern, the second electrically conductive pattern comprising a plurality of first solder pads; laminating a first lamination substrate onto the glass wiring substrate, the first lamination substrate comprising a first base layer and a first electrically conductive material layer on the first base layer, such that the first base layer is sandwiched between the first electrically conductive pattern and the first electrically conductive material layer; patterning the first electrically conductive material layer to form a third electrically conductive pattern, and electrically connecting the third electrically conductive pattern to the first electrically conductive pattern, and forming a first solder mask on the glass wiring substrate, thereby obtaining a multilayer printed circuit board.

### BACKGROUND

1. Technical Field

The present disclosure generally relates to printed circuit boards, and particularly to a multilayer printed circuit board and a method for manufacturing the multi-layer printed circuit board.

2. Description of Related Art

To accommodate the development of miniaturized electronic products with multiple functions, multilayer printed circuit boards are widely used due to their characteristics such as lightness and high-density inter-connectability.

The multilayer printed circuit boards usually include a substrate made of organic resin material and conductive electrical traces formed on the substrate. However, because thermal expansion coefficient of the organic resin greatly differ from thermal expansion coefficient of chips made of silicon, when the chips are arranged on the multilayer printed circuit board, conductive electrical traces between the substrate and the chips easily cut off, thereby shortening lifetime of the multilayer printed circuit board.

What is needed, therefore, is a multilayer printed circuit board and a method for manufacturing the multilayer printed circuit board to overcome the above-described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIGS. 1-8 show successive stages in the making of a multilayer printed circuit board according to a first embodiment.

FIGS. 9-16 show successive stages in the making of a multilayer printed circuit board according to a second embodiment.

### DETAILED DESCRIPTION

A method for manufacturing a multilayer printed circuit board and a multilayer printed board according to embodiments will be described with reference to the drawings.

A method of manufacturing a multilayer printed circuit board according to a first embodiment includes the steps as follows.

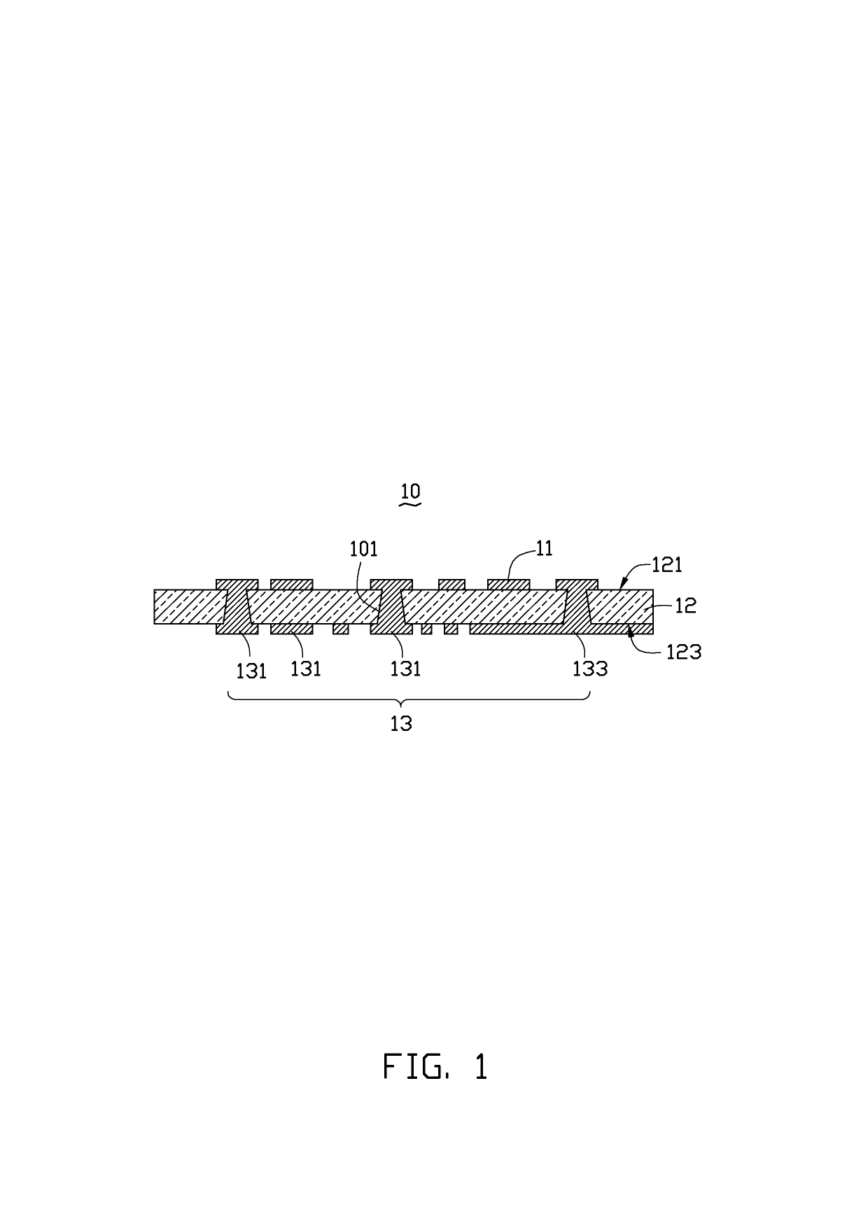

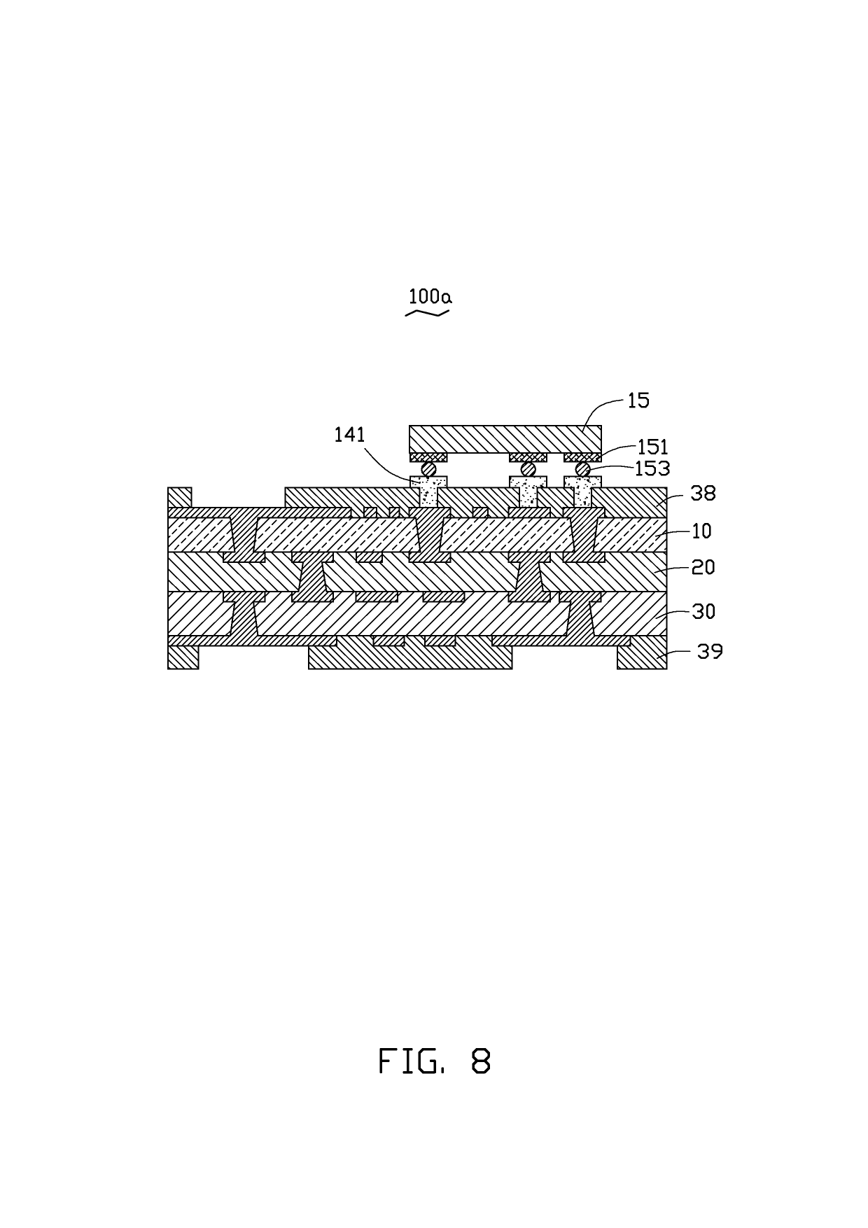

FIG. 1 shows in step 1, a glass wiring substrate 10 is provided. The glass wiring substrate 10 includes a first electrically conductive pattern 11, a glass base 12, and a second electrically conductive pattern 13 stacked in the above-described order. The glass base 12 includes a first surface 121 and an opposite second surface 123. The first electrically conductive pattern 11 is formed on the first surface 121 by selectively etching electrically conductive material (e.g. copper, silver, or golden etc.), and includes electrically conductive wires and solder pads. The second electrically conductive pattern 13 is formed on the second surface 123 by a subtractive process or a semi-additive process, and includes electrically conductive wires and solder pads. The first electrically conductive pattern 11 is electrically connected to the second electrically conductive pattern 13 via at least one plating through hole 101 arranged in the glass base 12. The second electrically conductive pattern 13 includes a plurality of first solder pads 131 and a plurality of second solder pads 133. The first solder pads 131 are configured for positioning a flip-chip 15 (see FIG. 8) electrically connected to the glass wiring substrate 10 by a Flip-chip technology. The second solder pads 133 are configured for positioning other electronic element (except flip chip), for example resistor, capacitor, diode, for example by surface mounted technology.

The first plating through hole 101 may be formed before forming the first electrically conductive pattern 11 and the second electrically conductive pattern 13, and can be formed by the steps as follows: at least one through hole is formed in the glass base 12 by a laser beam or a blanking die; electrically conductive material is deposited in the corresponding through hole by a coating process, thereby forming the plating through hole 101.

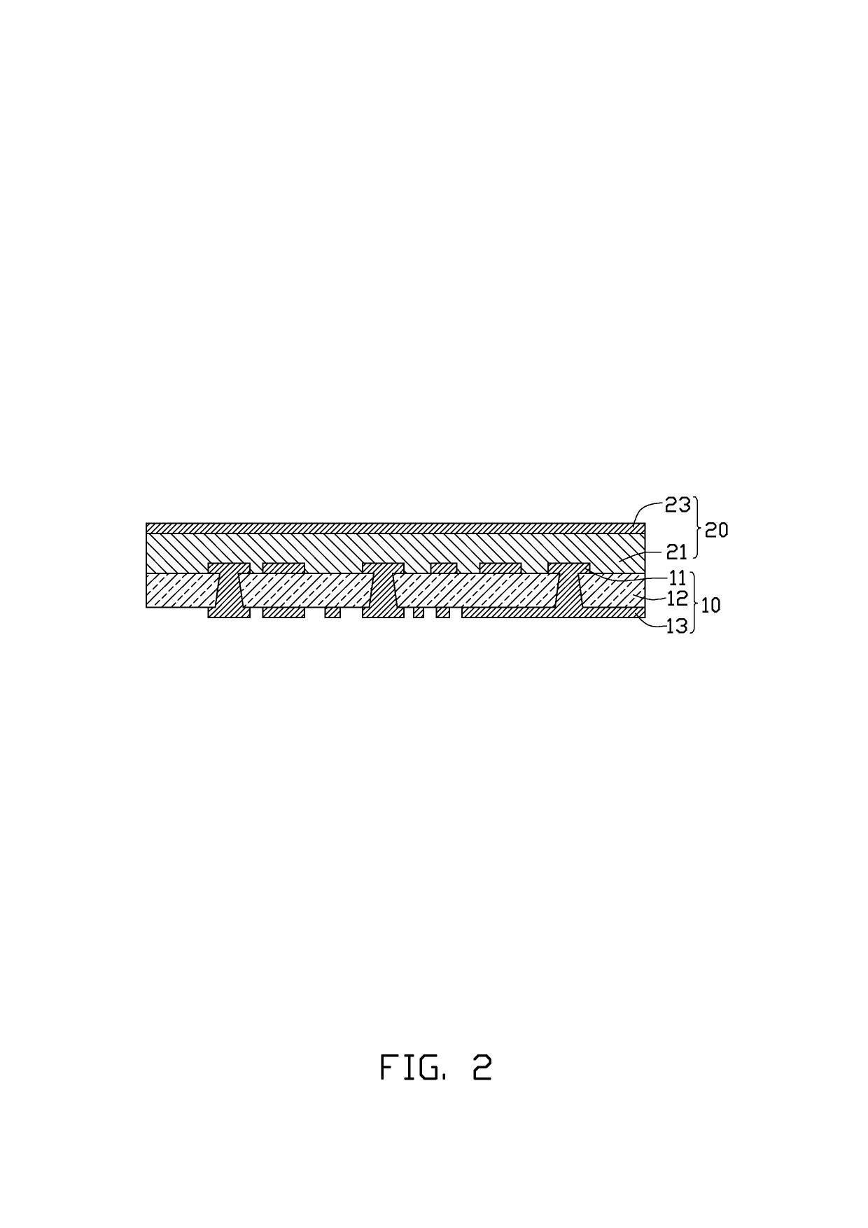

FIG. 2 shows in step 2, a first lamination substrate 20 is provided. The first lamination substrate 20 includes a first base layer 21 and a first electrically conductive material layer 23 adhered to the first base layer 21. The first base layer 21 can be made of organic material (e.g. Bismaleimide Triazine, Ajinomoto Buildup Film, Polyimide, for example). The first electrically conductive material layer 23 can be made of electrically conductive material (e.g. copper, silver, gold, for example). In the present embodiment, the first electrically conductive material layer 23 is a copper foil layer.

Then, the first lamination substrate 20 is laminated onto the glass wiring substrate 10, such that the first base layer 21 is positioned between the first electrically conductive pattern 11 and the first electrically conductive material layer 23.

It is understood that there may be an adhesive sheet between the glass wiring substrate 10 and the first lamination substrate 20 for improving adhesive force between the glass wiring substrate 10 and the first lamination substrate 20.

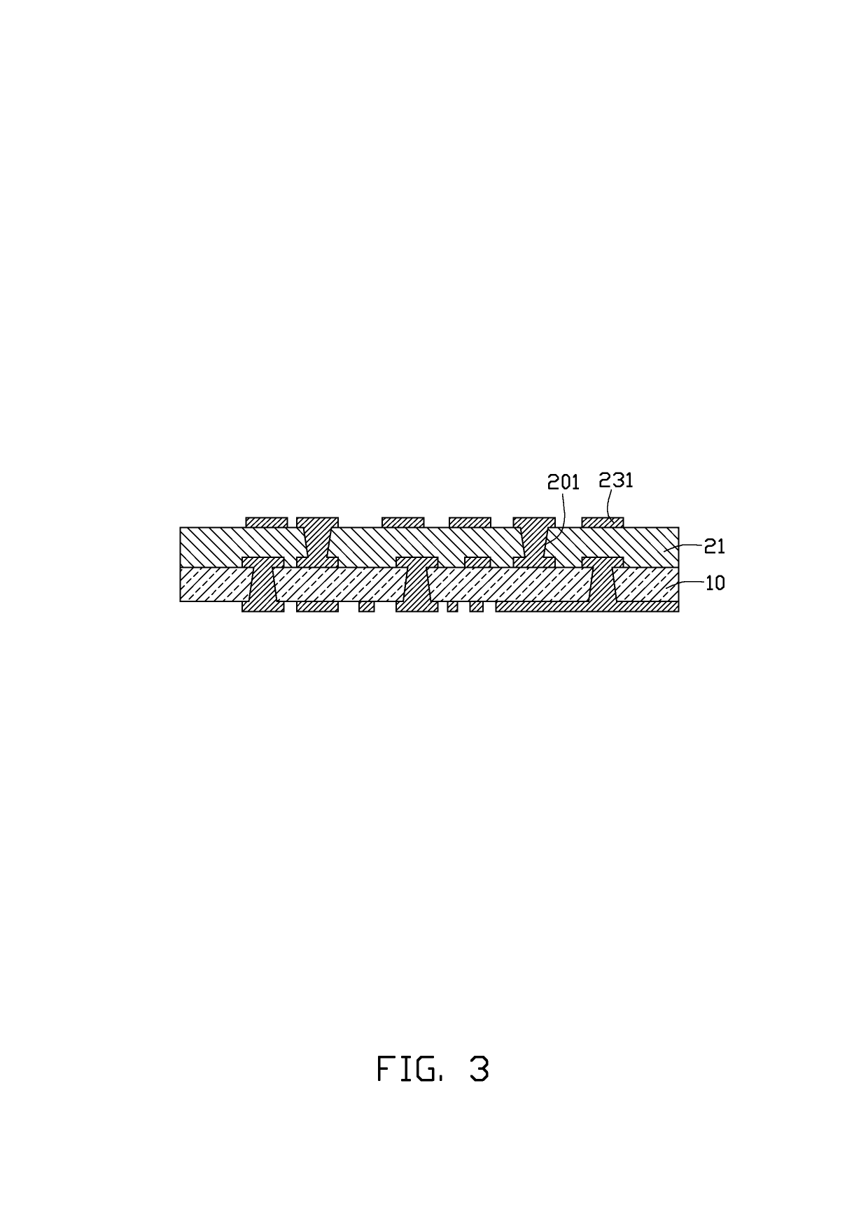

FIG. 3 shows in step 3, that the first electrically conductive material layer 23 is patterned to obtain a third electrically conductive pattern 231 by a subtractive process or a semi-additive process, and the third electrically conductive pattern 231 is electrically connected to the first electrically conductive pattern 111. In the present embodiment, the first electrically conductive material layer 23 is selectively etched by chemical solution, thereby removing unwanted first electrically conductive material and keeping wanted first electrically conductive material to form the third electrically conductive pattern 231. The third electrically conductive pattern 231 includes electrically conductive wires and solder pads.

The first electrically conductive pattern 11 is electrically connected to the third electrically conductive pattern 231 via at least one second plating through hole 201 in the first base layer 21. The at least one second plating through hole 201 can be formed before forming the third electrically conductive pattern 231, and can be formed, for example, by the following steps: at least one through hole is formed in the first base layer 21 by a laser beam or a blanking die; electrically conductive material is deposited in the corresponding through hole by a coating process, thereby forming the at least one second plating through hole 201.

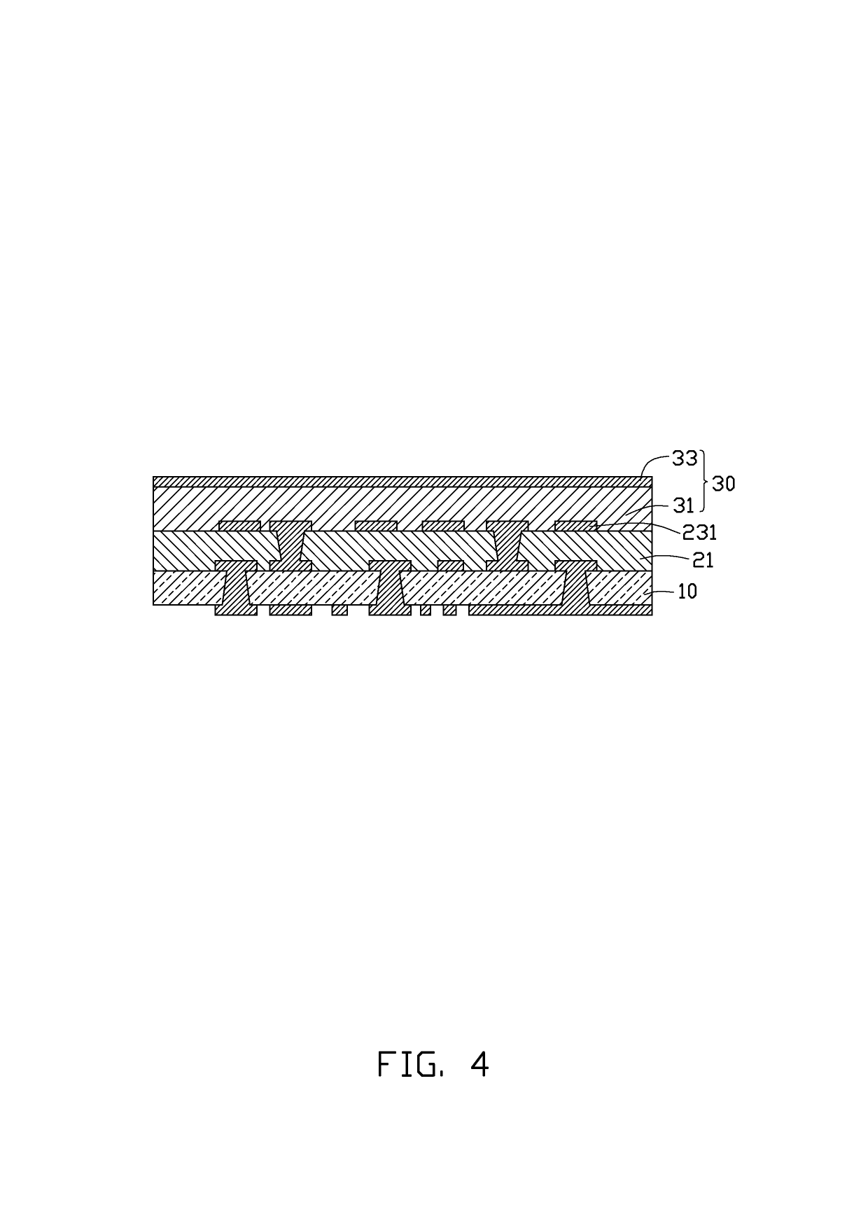

FIG. 4 shows in step 4, that a second lamination substrate 30 is provided. The second lamination substrate 30 includes a second base layer 31 and a second electrically conductive material layer 33 adhered to the second base layer 31. The second base layer 31 can be made of organic material (e.g. Bismaleimide Triazine, Ajinomoto Buildup Film, Polyimide, etc.). The second electrically conductive material layer 33 can be made of electrically conductive material (e.g. copper, silver, golden, etc.). In the present embodiment, the second electrically conductive material layer 33 is a copper foil layer.

Then, the second lamination substrate 30 is laminated onto the first lamination substrate 20, such that the second base layer 31 is positioned between the third electrically conductive pattern 231 and the second electrically conductive material layer 33.

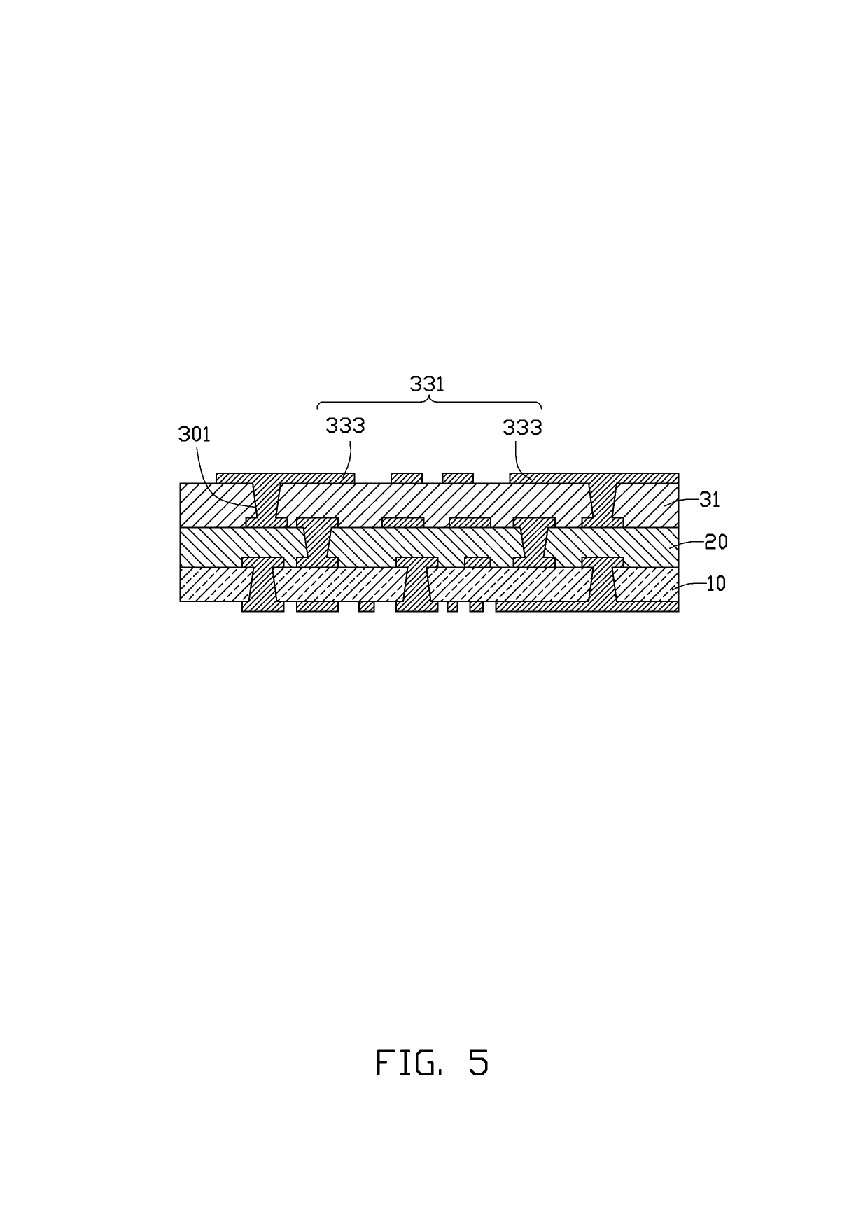

FIG. 5 shows in step 5, that the second electrically conductive material layer 33 is patterned to obtain a fourth electrically conductive pattern 331 by a subtractive process or a semi-additive process, and the fourth electrically conductive pattern 311 is electrically connected to the third electrically conductive pattern 231. In the present embodiment, the second electrically conductive material layer 33 is selectively etched by chemical solution, thereby removing unwanted second electrically conductive material and keeping wanted second electrically conductive material to form the fourth electrically conductive pattern 331 including electrically conductive wires and solder pads. The fourth electrically conductive pattern 331 includes a plurality of third solder pads 333. The third solder pads 333 are electrically connected to other printed circuit board or other electrical element via electrically conductive adhesive (not shown).

The fourth electrically conductive pattern 331 is electrically connected to the third electrically conductive pattern 231 via at least one third plating through hole 301 in the second base layer 31. The at least one third plating through hole 301 can be made by a method similar to the method for making the second plating through hole 201.

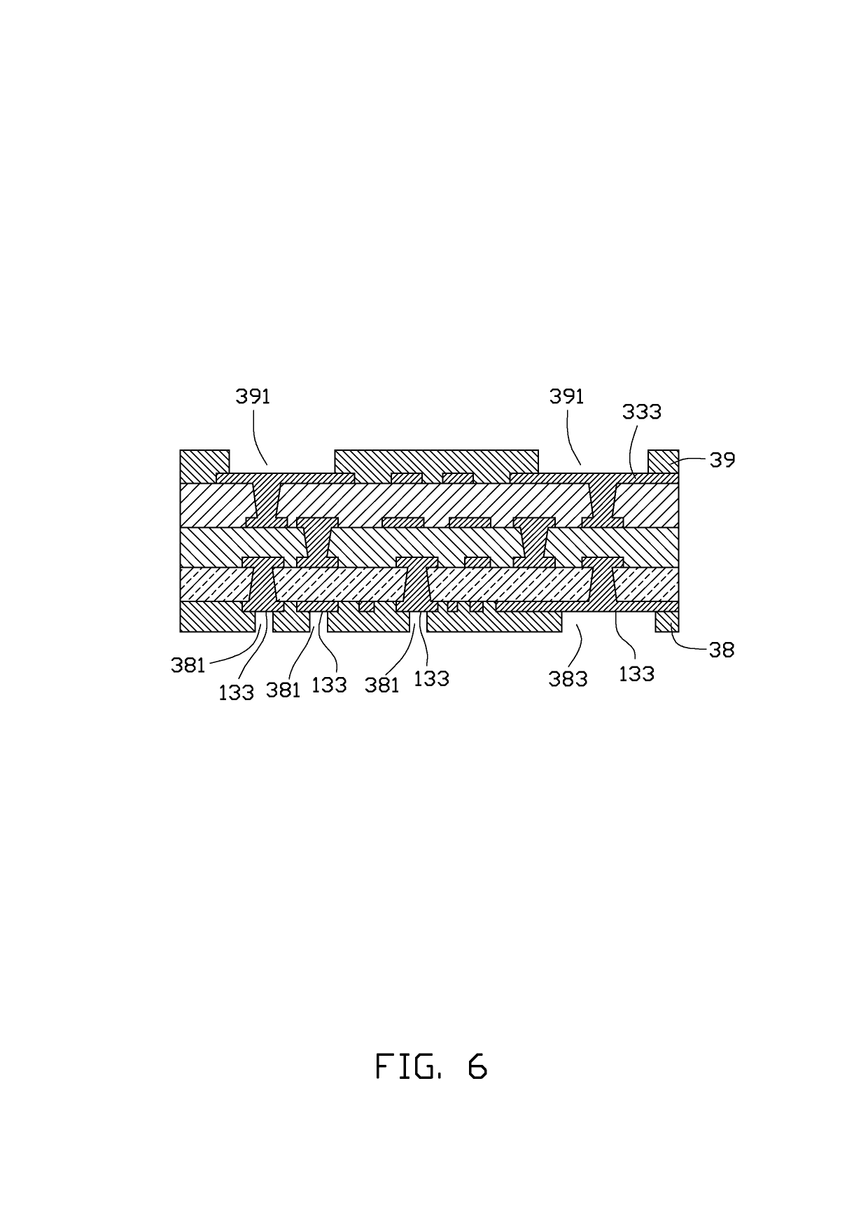

FIG. 6 show in step 6, that a first solder mask 38 is formed on the glass wiring substrate 10 by printing, adhering, or spraying, and a second solder mask 39 is formed on the second lamination substrate 30 by printing, adhering, or spraying. The first solder mask 38 is configured for protecting the second electrically conductive pattern 13 form damage. The first solder mask 38 includes a plurality of first openings 381 and a plurality of second openings 383. The first openings 381 spatially correspond to the first solder pads 131, respectively, thereby exposing the first solder pads 131. The second openings 383 spatially correspond to the second solder pads 133, respectively, thereby exposing the second solder pads 133. The second solder mask 39 is configured for protecting the fourth electrically conductive pattern 331. The second solder mask 39 includes a plurality of third openings 391 spatially corresponding to the third solder pads 333, thereby exposing the third solder pads 333.

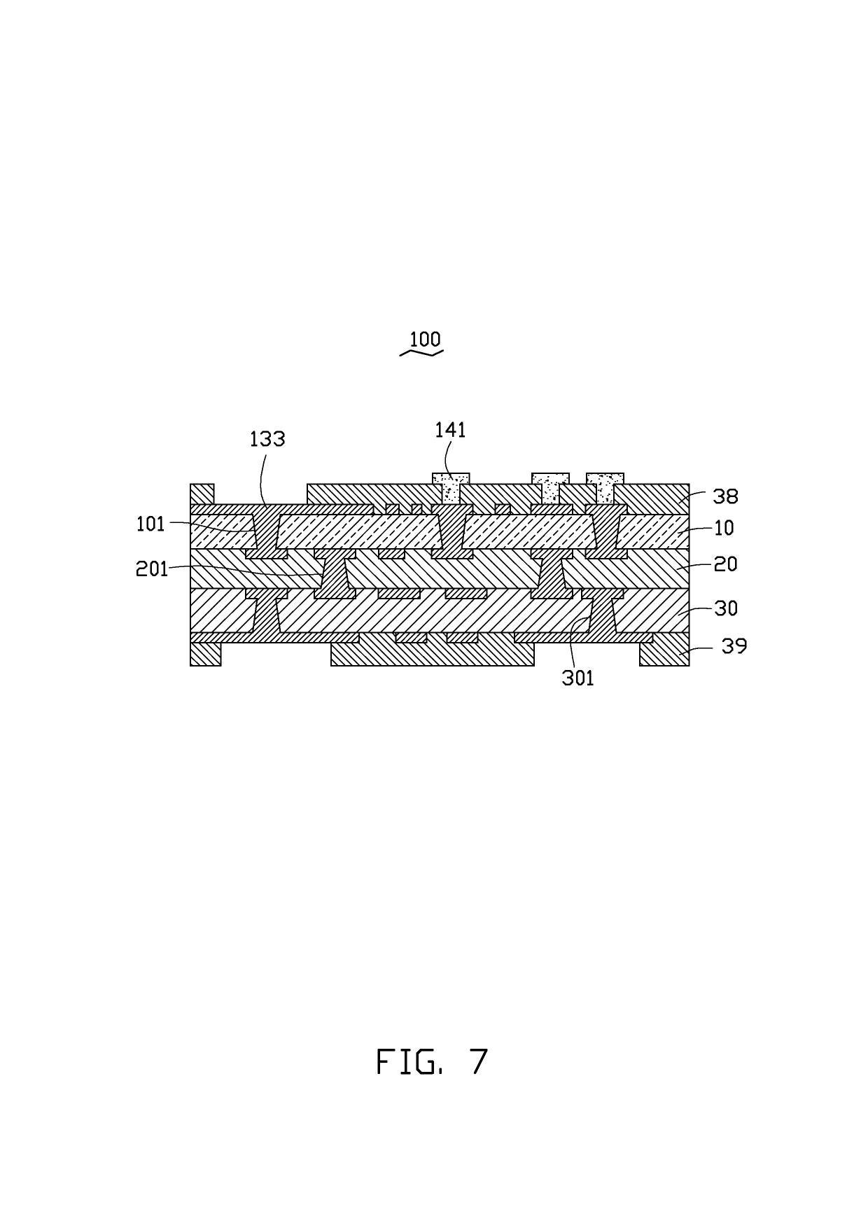

FIG. 7 shows in step 7, that a flip chip solder 141 is formed on a surface of each first solder pad 131 exposed to outside by printing or electroplating, thereby forming a multilayer printed circuit board 100 having a plurality of flip chip solders 141. The plurality flip chip solder 141 is configured for positioning the flip chip 15 electrically connected to the glass wiring substrate 10 by the flip chip technology. Each of the flip chip solder 141 can be made of tin, lead-tin alloy, or silver-tin alloy, for example In the present embodiment, each flip chip solder 141 protrudes the corresponding first opening 381, such that an assembly of the flip chip 15 on the flip chip solder 141 is easy. Accordingly, the multilayer printed circuit board 100 having a plurality of flip chip solders 141 is obtained.

FIG. 8 shows in step 8, that the flip chip 15 is arranged on the flip chip solders 141, thereby forming a multilayer printed circuit board 100a having the flip chip 15. The flip chip 15 includes a plurality of connection terminals 151. Each of the connection terminals 151 is electrically connected to the corresponding flip chip solder 141 through a solder ball 151, thereby achieving electrical connection between the flip chip 15 and the glass wiring substrate 10.

The multilayer printed circuit board 100a includes a glass wiring substrate 10, a first lamination substrate 20 and a second lamination substrate 30 stacked in the above-described order. The glass wiring substrate 10, the first plating through hole 101, the second plating through hole 201 and the third plating through hole 301 electrically connect the first lamination substrate 20, and the second lamination substrate 30 to each other. The glass wiring substrate 10 includes the second electrically conductive pattern 13, the glass base 12 and the first electrically conductive pattern 11 stacked in the above-described order. The second electrically conductive pattern 13 includes a plurality of first solder pads 131. The first solder mask 38 is formed on the surface of the glass wiring substrate 10, and includes a plurality of first openings 381 spatially corresponding to the first solder pads 131, respectively, thereby exposing the first solder pads 131. One flip chip solder 141 is formed on a surface of each exposed first solder pad 131. The flip chip solders 141 are configured for arranging the flip chip 15 electrically connected to the glass wiring substrate 10 by the flip chip technology.

In the multilayer printed circuit board 100a, because thermal expansion coefficient of glass is closer to thermal expansion coefficient of silicon than thermal expansion coefficient of organic resin, stress between the glass base 12 and chip made of silicon is hard to generate. Accordingly, electrically conductive wires in the second electrically conductive pattern 13 between the flip chip 15 made of silicon and the glass base 12 is hard to be broken, thereby lengthening lifetime of the multilayer printed circuit board 100a. In addition, because the surface of the glass base 12 is flatter than the surface of organic resin base, it is easier to form precise and super fine wires (i.e. L/S is smaller or equal to 10/10 um). Furthermore, the method of manufacturing the multilayer printed circuit board 100a is very simple, and process time is short. Accordingly, high production can be easily achieved when the multilayer printed circuit board 100a is in mass production.

Except for manufacturing a three-layer printed circuit board obtained by removing the first lamination substrate 20 from the multilayer printed circuit board 100a or other multilayer printed circuit including one glass wiring substrate, a multilayer printed circuit board including two, three, four, or more glass wiring substrates may be manufactured by a method similar to the above-described method. In detail, a method for manufacturing a multilayer printed circuit board according to a second embodiment includes the steps as follows.

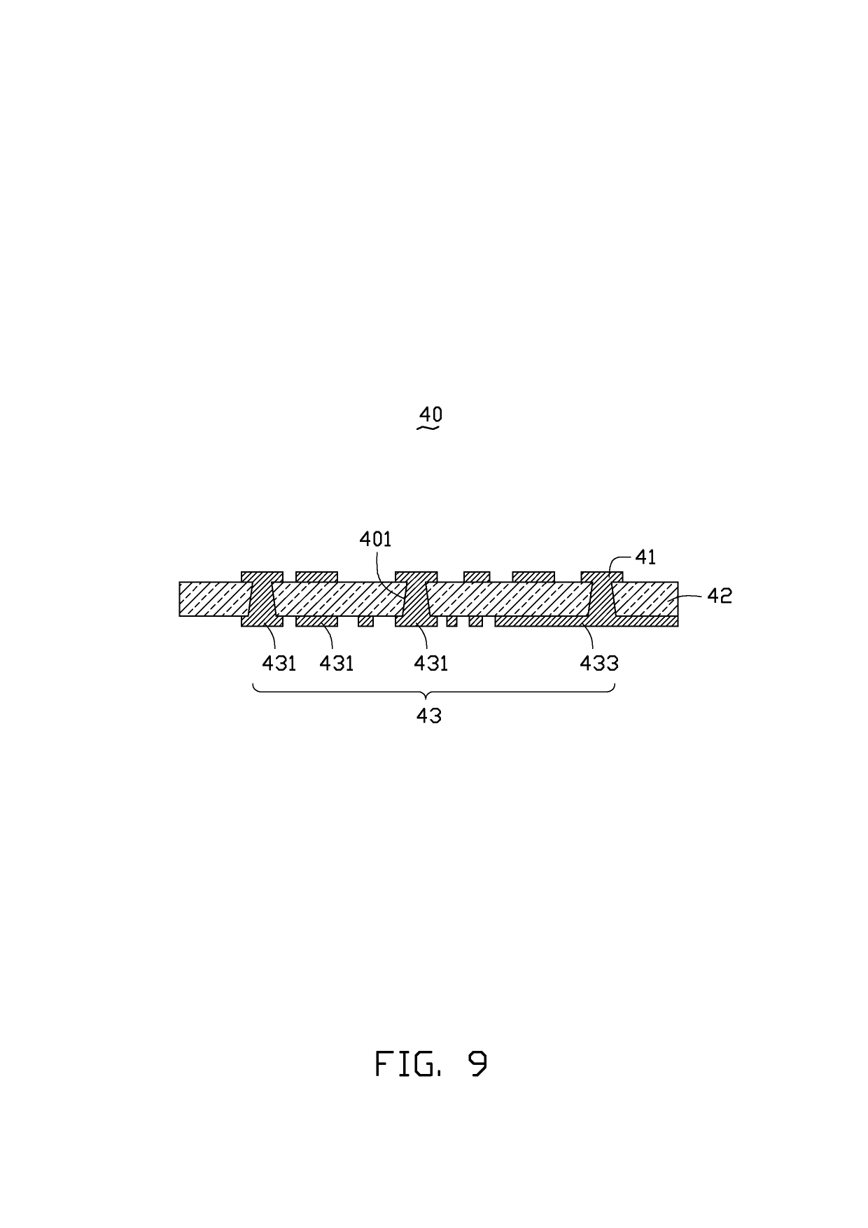

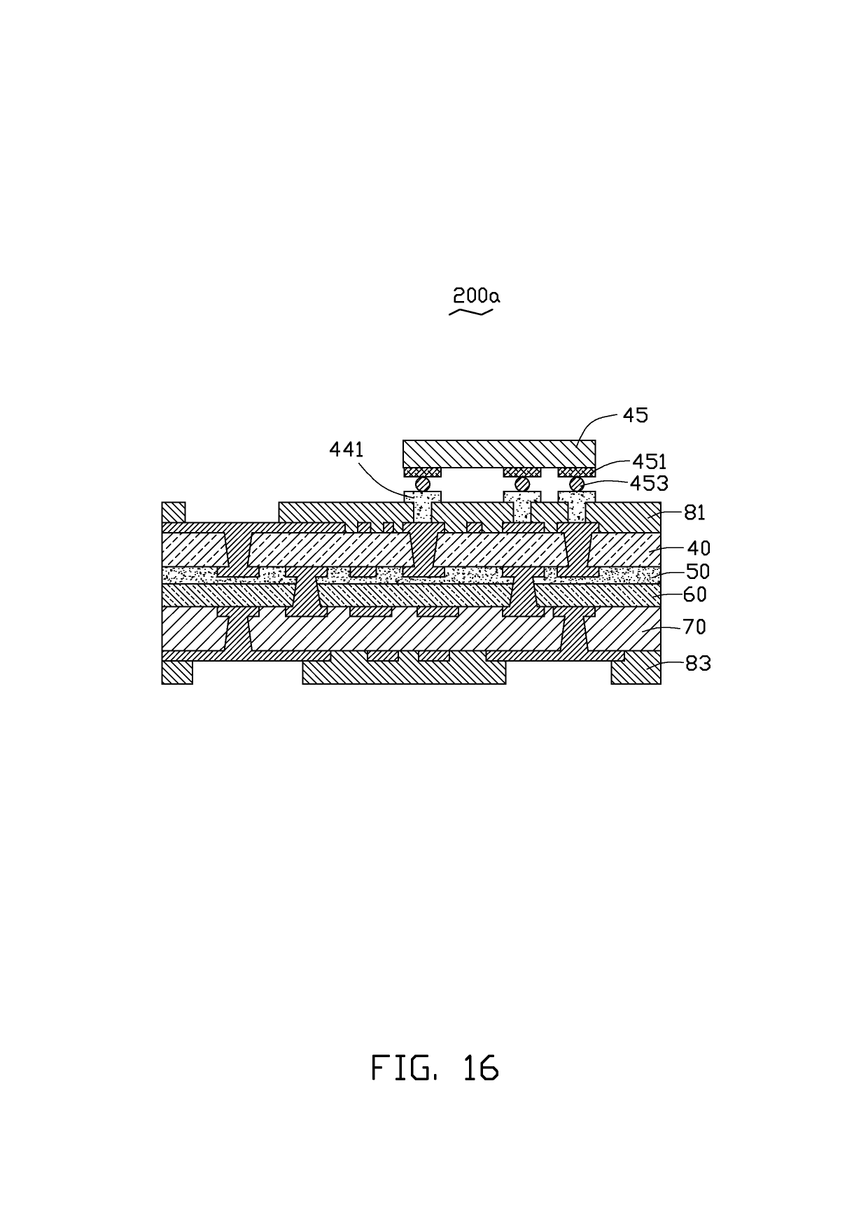

FIG. 9 shows in step 1, a glass wiring substrate 40 is provided. The glass wiring substrate 40 can be manufactured by a method similar to the method for manufacturing the glass wiring substrate 40. The glass wiring substrate 40 includes a first electrically conductive pattern 41, a glass base 42, and a second electrically conductive pattern 43 stacked in the above-described order. The glass base 12 is sandwiched between the first and second electrically conductive patterns 41, 43. The first electrically conductive pattern 41 is electrically connected to the second electrically conductive pattern 43 via at least plating through hole 401 arranged in the glass base 42. The second electrically conductive pattern 43 includes a plurality of first solder pads 431 and a plurality of second solder pads 433. The first solder pads 431 are configured for positioning a flip-chip 45 (see FIG. 16) electrically connected to the glass wiring substrate 40 by a Flip-chip technology. The second solder pads 133 are configured for positioning other electronic element (except flip chip), resistor, capacitor, or diode, for example by a surface mounted technology or a wire bonding technology.

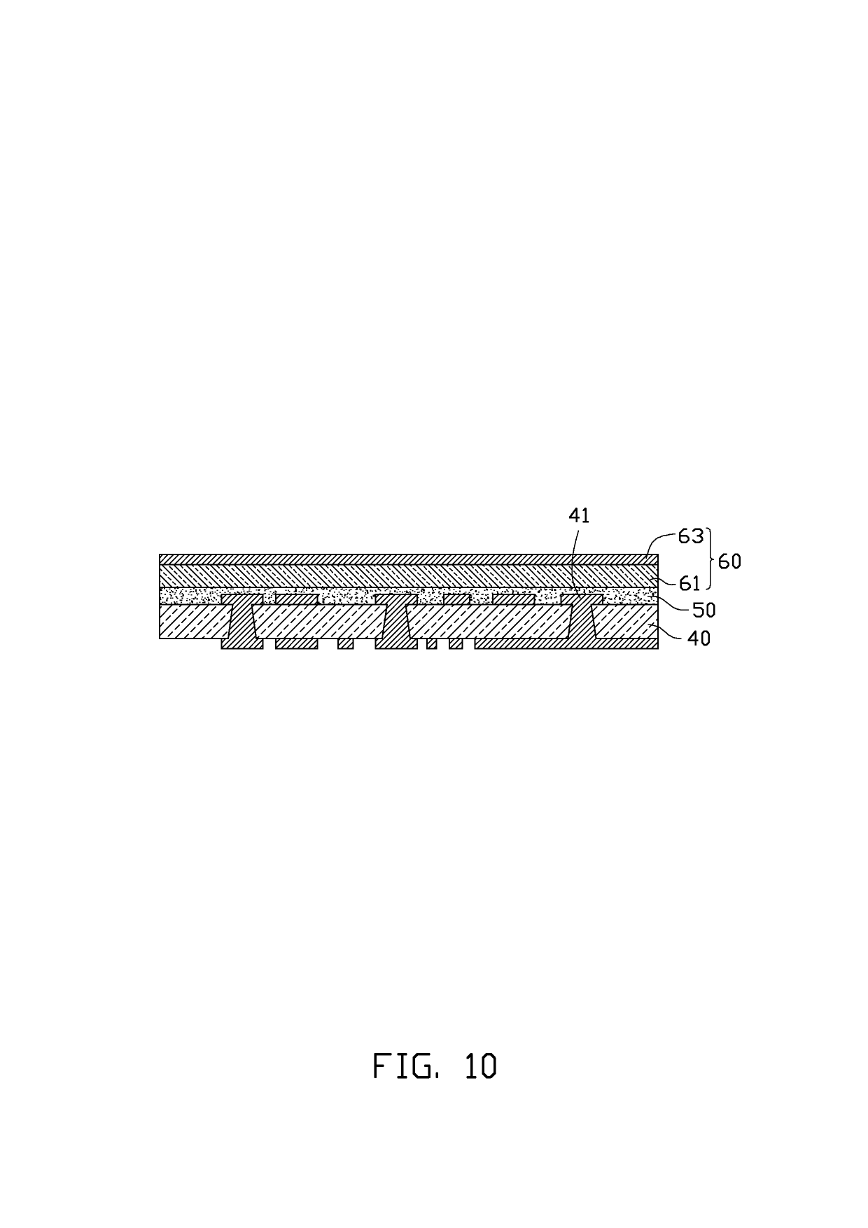

FIG. 10 shows in step 2, that a adhesive sheet 50 and a first lamination substrate 60 are provided. The adhesive sheet 50 is mainly comprised of polypropylenes resin and fiberglass, and is configured for adhering the first lamination substrate 60 to the glass wiring substrate 40. The first lamination substrate 60 includes a first base layer 61 and a first electrically conductive material layer 63 adhered to the first base layer 61. The first base layer 61 is made of glass. The first electrically conductive material layer 63 is made of electrically conductive material (e.g. copper, silver, gold, etc).

Then, the adhesive sheet 50 and the first lamination substrate 60 are laminated onto the glass wiring substrate 40, such that the adhesive sheet 50 is sandwiched between the first electrically conductive pattern 41 and the first base layer 61.

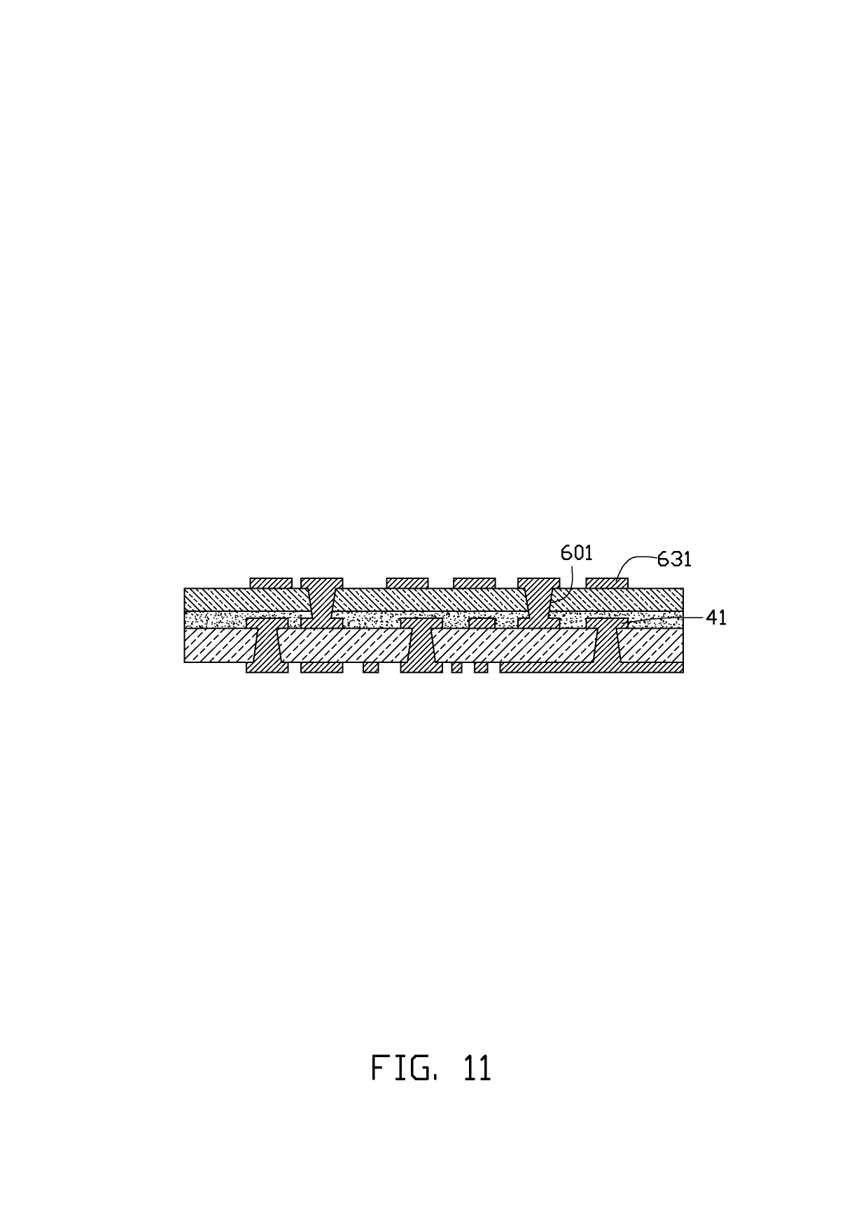

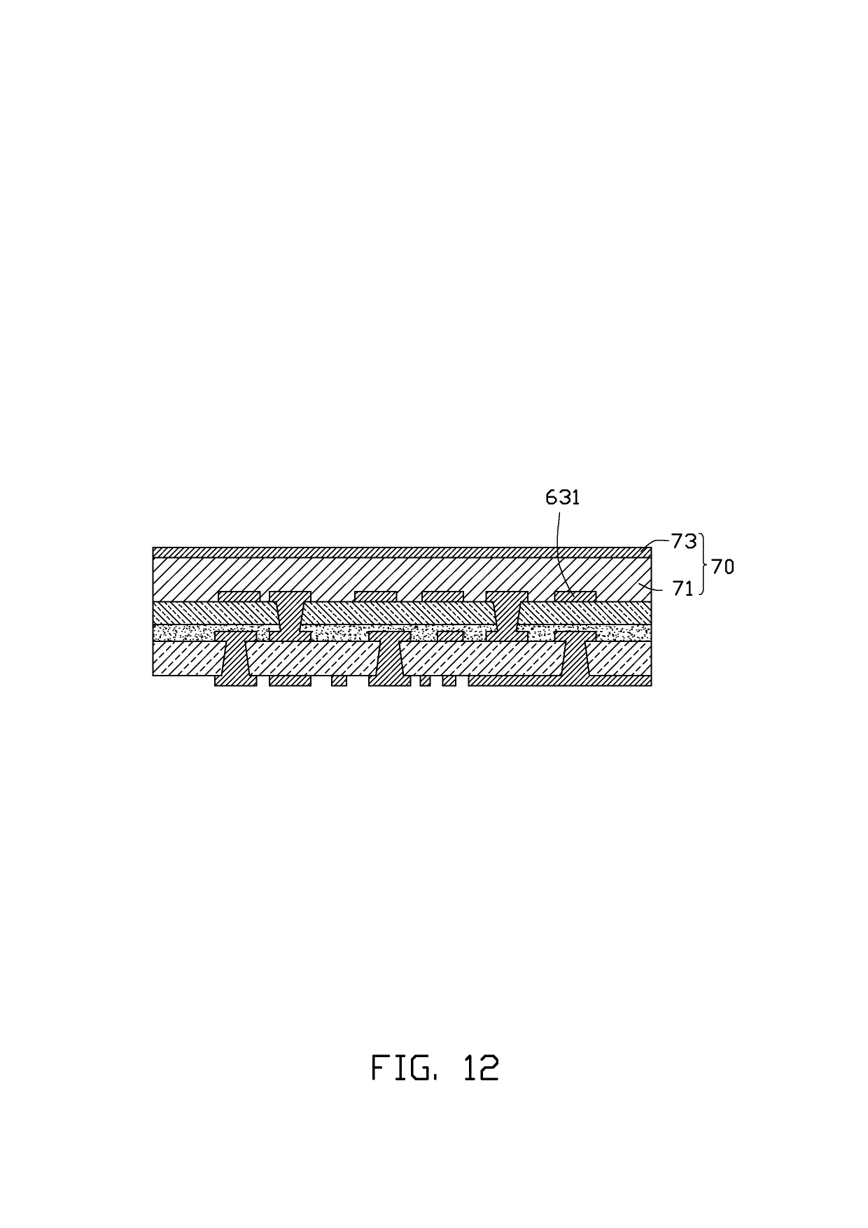

FIG. 11 shows in step 3, that the first electrically conductive material layer 63 is patterned to obtain a third electrically conductive pattern 631 by a subtractive process or a semi-additive process, and the third electrically conductive pattern 631 is electrically connected to the first electrically conductive pattern 41. In the present embodiment, the first electrically conductive material layer 63 is selectively etched by chemical solution, thereby removing unwanted first electrically conductive material and keeping wanted first electrically conductive material to form third electrically conductive pattern 631. The third electrically conductive pattern 631 includes electrically conductive wires.

The first electrically conductive pattern 41 is electrically connected to the third electrically conductive pattern 631 via at least one second plating through hole 601 in the first base layer 61. The at least one second plating through hole 601 can be formed after laminating the first lamination substrate 60, the adhesive sheet 50 and the glass wiring substrate 40, and before forming the third electrically conductive pattern 231, for example, by the following steps: at least one through hole is formed in the firs lamination substrate 60 and the adhesive sheet 50 by a laser beam or a blanking die, each of the through hole passes through the first electrically conductive material layer 63, the first base layer 61 and adhesive sheet 50; electrically conductive material is deposited in the corresponding through hole by a coating process, thereby forming the at least one second plating through hole 201 electrically connecting the first electrically conductive pattern 41 to the first electrically conductive material layer 63.

FIG. 4 shows in step 4, that a second lamination substrate 70 is provided. The second lamination substrate 70 includes a second base layer 71 and a second electrically conductive material layer 73 adhered to the second base layer 31. The second base layer 71 can be made of organic material (e.g. Bismaleimide Triazine, Ajinomoto Buildup Film, Polyimide, for example).

The second electrically conductive material layer 73 can be made of electrically conductive material (e.g. copper, silver, golden, etc.). In the present embodiment, the second electrically conductive material layer 73 is a copper foil layer.

Then, the second lamination substrate 70 is laminated onto the first lamination substrate 60, such that the second base layer 71 is positioned between the third electrically conductive pattern 631 and the second electrically conductive material layer 73.

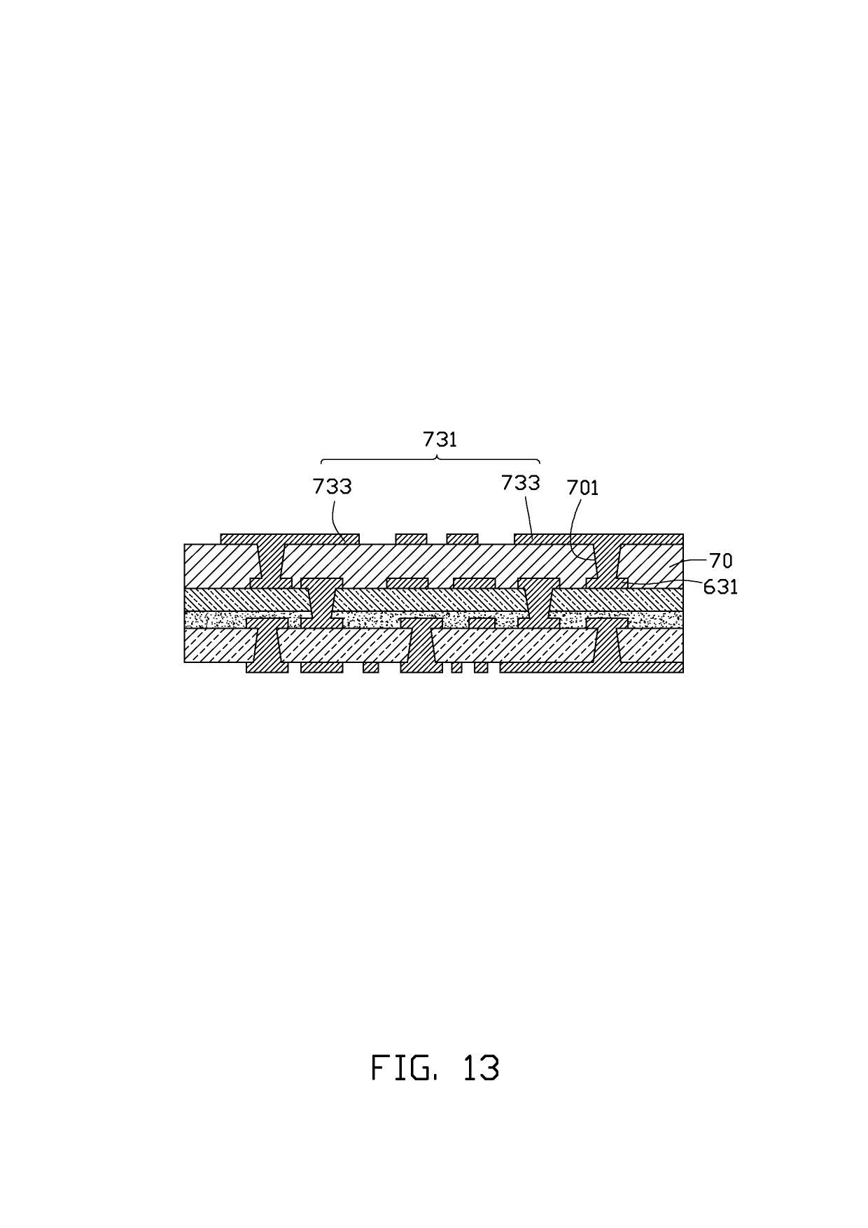

FIG. 13 shows in step 5, that the second electrically conductive material layer 73 is patterned to obtain a fourth electrically conductive pattern 731 by a subtractive process or a semi-additive process, and the fourth electrically conductive pattern 731 is electrically connected to the third electrically conductive pattern 631. In the present embodiment, the second electrically conductive material layer 73 is selectively etched by chemical solution, thereby removing unwanted second electrically conductive material and keeping wanted second electrically conductive material to form the fourth electrically conductive pattern 731 including electrically conductive wires and solder pads. The fourth electrically conductive pattern 731 includes a plurality of third solder pads 733. The third solder pads 733 are electrically connected to other printed circuit board or other electrical element through electrically conductive adhesive (not shown).

The fourth electrically conductive pattern 731 is electrically connected to the third electrically conductive pattern 631 via at least one third plating through hole 701 in the second base layer 71. The at least one third plating through hole 701 can be made after laminating the first lamination substrate 60 and the second lamination substrate 70, and before the fourth electrically conductive pattern 731, and can be made by a method similar to the method for making the second plating through hole 601, for example.

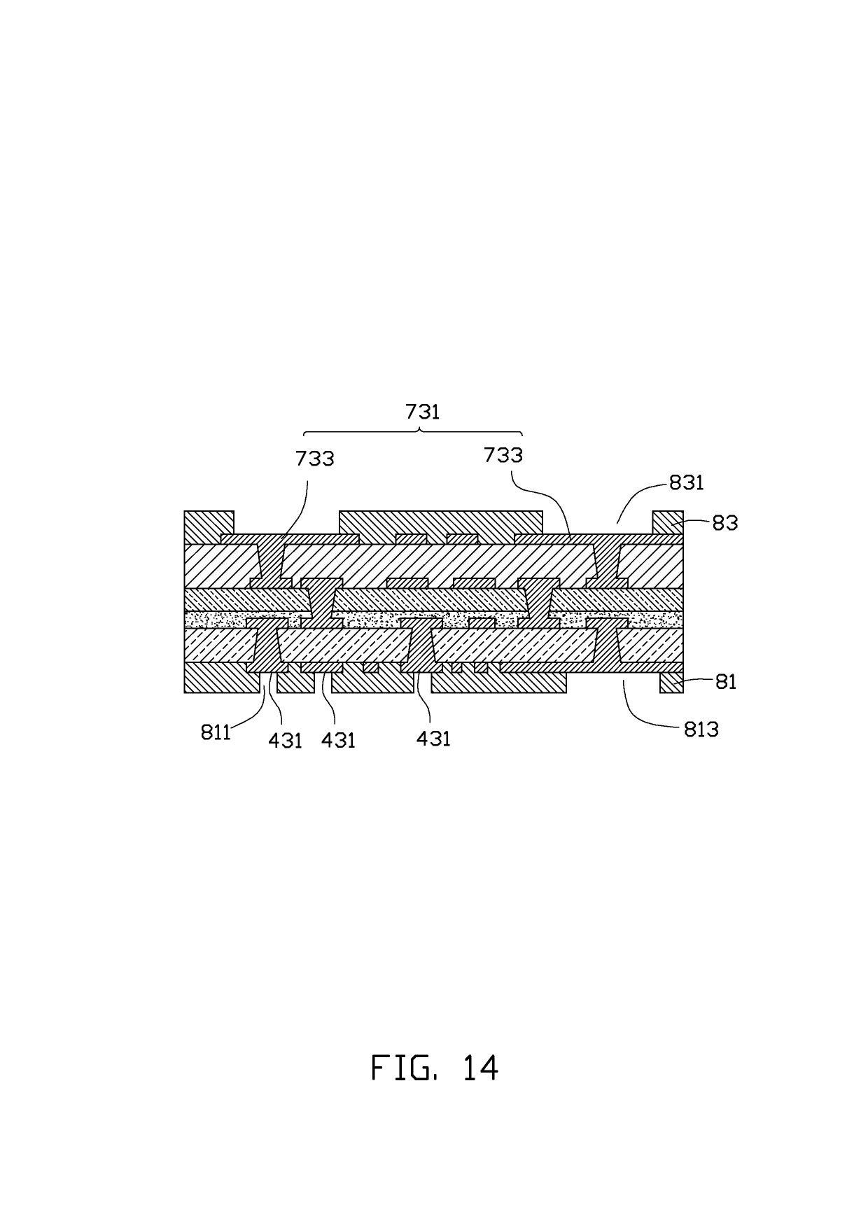

FIG. 14 shows in step 6, that a first solder mask 81 is formed on the glass wiring substrate 40 by printing, adhering, or spraying, and a second solder mask 83 is formed on the second lamination substrate 70 by printing, adhering, or spraying. The first solder mask 81 is configured for protecting the second electrically conductive pattern 43 from damage. The first solder mask 81 includes a plurality of first openings 811 and a plurality of second openings 813. The first openings 811 spatially correspond to the first solder pads 431, respectively, thereby exposing the first solder pads 431. The second openings 813 spatially correspond to the second solder pads 433, respectively, thereby exposing the second solder pads 433. The second solder mask 83 is configured for protecting the fourth electrically conductive pattern 731. The second solder mask 83 includes a plurality of third openings 831 spatially corresponding to the third solder pads 733, thereby exposing the third solder pads 733.

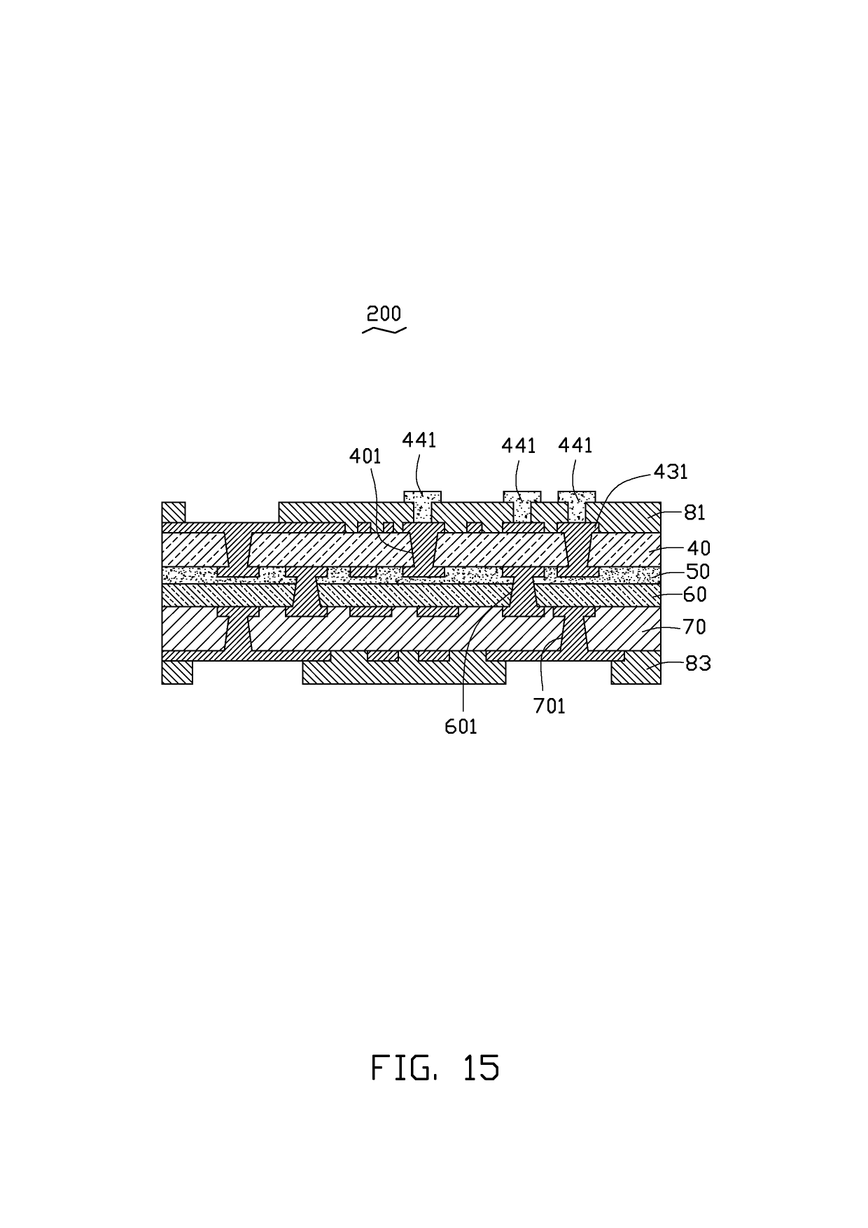

FIG. 15 shows in step 7, that a flip chip solder 441 is formed on a surface of each first solder pad 431 exposed to outside by printing or electroplating, thereby forming a multilayer printed circuit board 200 having a plurality of flip chip solders 441. The flip chip solder 441 is configured for arranging the flip chip 45 electrically connected to the glass wiring substrate 40 by the flip chip technology. Each of the flip chip solder 441 can be made of tin, lead-tin alloy, or silver-tin alloy, for example. In the present embodiment, each flip chip solder 441 protrudes from the corresponding first opening 811, such that it is easy to assemble the flip chip 45 on the flip chip solder 441. Accordingly, the multilayer printed circuit board 200 having a plurality of flip chip solders 441 is obtained.

FIG. 16 shows in step 8, that the flip chip 45 is arranged on the flip chip solder 441, thereby forming a multilayer printed circuit board 200a having the flip chip 45. The flip chip 45 includes a plurality of connection terminals 451. Each of the connection terminals 451 is electrically connected to the corresponding one flip chip solder 441 through a solder ball 453, thereby achieving electrical connection between the flip chip 45 and the glass wiring substrate 10.

The multilayer printed circuit board 200a includes a glass wiring substrate 40, a first lamination substrate 60 and a second lamination substrate 70 stacked in the above-described order. The glass wiring substrate 40, the first plating through hole 401, the second plating through hole 601 and the third plating through hole 701 electrically connect the first lamination substrate 60, and the second lamination substrate 70 to each other. The glass wiring substrate 40 includes the second electrically conductive pattern 43, the glass base 42 and the first electrically conductive pattern 41 stacked in the above-described order. The second electrically conductive pattern 43 includes a plurality of first solder pads 431. The first solder mask 81 is formed on the surface of the glass wiring substrate 40, and includes a plurality of first openings 811 spatially corresponding to the first solder pads 431, respectively, thereby exposing the first solder pads 431. One flip chip solder 441 is formed on a surface of each exposed first solder pad 431. The flip chip solders 441 are configured for arranging the flip chip 45 electrically connected to the glass wiring substrate 40 by the flip chip technology.

In the multilayer printed circuit board 200a, because thermal expansion coefficient of glass is closer to thermal expansion coefficient of silicon than thermal expansion coefficient of organic resin, stress between the glass base 42 and chip made of silicon is hard to generate. Accordingly, electrically conductive wires in the second electrically conductive pattern 43 between the flip chip 45 made of silicon and the glass base 42 is hard to be broken, thereby lengthening lifetime of the multilayer printed circuit board 200a. In addition, because the surface of the glass base 42 is flatter than the surface of organic resin base, it is easier to form precise and super fine wires (i.e. L/S is smaller or equal to 10/10 um). Furthermore, the method of manufacturing the multilayer printed circuit board 200a is very simple, and process time is short. Accordingly, high production can be easily achieved when the multilayer printed circuit board 200a is in mass production.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for manufacturing a multilayer printed circuit board, comprising:
providing a glass wiring substrate, the glass wiring substrate comprising a first electrically conductive pattern, a glass base, and a second electrically conductive pattern, the glass base being sandwiched between the first electrically conductive pattern and the second electrically conductive pattern, the first electrically conductive pattern being electrically connected to the second electrically conductive pattern via at least one plating through hole in the glass base, the second electrically conductive pattern comprising a plurality of first solder pads;
laminating a first lamination substrate onto the glass wiring substrate, the first lamination substrate comprising a first base layer and a first electrically conductive material layer on the first base layer, such that the first base layer is sandwiched between the first electrically conductive pattern and the first electrically conductive material layer;
patterning the first electrically conductive material layer to form a third electrically conductive pattern, and electrically connecting the third electrically conductive pattern to the first electrically conductive pattern, and
forming a first solder mask on the glass wiring substrate, the first solder mask comprising a plurality of first openings aligned with the respective first solder pads, thereby exposing the first solder pads to obtain a multilayer printed circuit board.

2. The method of claim 1, wherein the first electrically conductive pattern and the second electrically conductive pattern are formed by a subtractive process or a semi-additive process.

3. The method of claim 1, wherein the first base layer is made of glass, the method further comprises a step of providing an adhesive sheet, when the first lamination substrate is laminated onto the glass wiring substrate, the adhesive sheet is laminated between the glass wiring substrate and the first lamination substrate, such that the adhesive sheet is sandwiched between the first electrically conductive pattern and the first base layer.

4. The method of claim 1, wherein the first base layer is made of organic resin.

5. The method of claim 1, wherein before forming the first solder mask on the glass wiring substrate and after patterning the first electrically conductive material layer to be the third electrically conductive pattern, the method further comprises:
laminating a second lamination substrate onto the first lamination substrate, the second lamination substrate comprises a second base layer and a second electrically conductive material layer on the second base layer, such that the second base layer is sandwiched between the third electrically conductive pattern and the second electrically conductive material layer, and
patterning the second electrically conductive material layer to obtain a fourth electrically conductive pattern, and electrically connecting the fourth electrically conductive pattern to the third electrically conductive pattern, the fourth electrically conductive pattern comprising a plurality of third solder pads

6. The method of claim 5, further comprising a step of forming a second solder mask on the second base layer, the second solder mask comprises a plurality of third openings corresponding to the third solder pads, thereby exposing the third solder pads.

7. The method of claim 5, wherein the first base layer is made of glass or organic resin, and the second base layer is made of organic resin.

8. The method of claim 1, further comprising:
forming a flip chip solder on each first solder pad, and
positioning a flip chip on the flip chip solders, the flip chip comprising a plurality of connection terminals, each connection terminal being electrically connected to one flip chip solder via a solder ball, thereby achieving electrical connection between the flip chip and the glass wiring substrate.

9. A multilayer printed circuit board, comprising:
a glass wiring substrate, the glass wiring substrate comprising a first electrically conductive pattern, a glass base, and a second electrically conductive pattern, the glass base being sandwiched between the first electrically conductive pattern and the second electrically conductive pattern, the first electrically conductive pattern being electrically connected to the second electrically conductive pattern via at least one plating through hole in the glass base, the second electrically conductive pattern comprising a plurality of first solder pads, the glass wiring substrate further comprising a first solder mask formed thereon, the first solder mask comprising a plurality of first openings spatially corresponding to the first solder pads, respectively, thereby exposing the first solder pads, and
a first lamination substrate laminated onto the glass wiring substrate, the first lamination substrate comprising a first base layer and a third electrically conductive pattern on the first base layer, the first base layer being sandwiched between first electrically conductive pattern and the third electrically conductive pattern, the third electrically conductive being electrically connected to the first electrically conductive pattern.

10. The multilayer printed circuit board of claim 9, wherein the first base layer is made of glass, the multilayer printed circuit board further comprises an adhesive sheet, the adhesive sheet is sandwiched between the first base layer and the first electrically conductive pattern.

11. The multilayer printed circuit board of claim 9, wherein the multilayer printed circuit board further comprises a second lamination substrate laminated onto the first lamination substrate, the second lamination substrate comprises a second base layer and a fourth electrically conductive pattern, the second base layer is sandwiched between the third electrically conductive pattern and the fourth electrically conductive pattern, the third electrically conductive pattern is electrically connected to the second electrically conductive pattern, the fourth electrically conductive pattern comprises a plurality of third solder pads, the second base layer further comprises a second solder mask, the second solder mask comprises a plurality of third openings spatially corresponding to the third solder pads, thereby exposing the third solder pads.

12. The multilayer printed circuit board of claim 11, wherein the first base layer is made of glass or organic resin, and the second base layer is made of glass or organic resin.

13. A multilayer printed circuit board, comprising:
a glass wiring substrate, the glass wiring substrate comprising a first electrically conductive pattern, a glass base, and a second electrically conductive pattern, the glass base being sandwiched between the first electrically conductive pattern and the second electrically conductive pattern, the first electrically conductive pattern being electrically connected to the second electrically conductive pattern by at least one plating through hole in the glass base, the second electrically conductive pattern comprising a plurality of first solder pads, the glass wiring substrate further comprising a first solder mask formed thereon, the first solder mask comprising a plurality of first openings spatially corresponding to the first solder pads, respectively, thereby exposing the first solder pads, the glass wiring substrate further comprising a plurality of flip chip solders corresponding to the first solder pad, respectively, each flip chip solder formed on one first solder pad;
a first lamination substrate laminated onto the glass wiring substrate, the first lamination substrate comprising a first base layer and a third electrically conductive pattern on the first base layer, the first base layer being sandwiched between first electrically conductive pattern and the third electrically conductive pattern, the third electrically conductive being electrically connected to the first electrically conductive pattern, and
a flip chip arranged on the flip chip solders, the flip chip comprising a plurality of connection terminals, each connection terminal being electrically connected to the corresponding flip chip solder through a solder ball, thereby achieving electrical connection between the flip chip and the glass wiring substrate.

14. The multilayer printed circuit board of claim 13, wherein the first base layer is made of glass, the multilayer printed circuit board further comprises a adhesive sheet, the adhesive sheet is sandwiched between the first base layer and the first electrically conductive pattern.

15. The multilayer printed circuit board of claim 13, wherein the multilayer printed circuit board further comprises a second lamination substrate laminated onto the first lamination substrate, the second lamination substrate comprises a second base layer and a fourth electrically conductive pattern, the second base layer is sandwiched between the third electrically conductive pattern and the fourth electrically conductive pattern, the third electrically conductive pattern is electrically connected to the second electrically conductive pattern, the fourth electrically conductive pattern comprises a plurality of third solder pads, the second base layer further comprises a second solder mask, the second solder mask comprises a plurality of third openings corresponding to the third solder pads, thereby exposing the third solder pads.

16. The multilayer printed circuit board of claim 15, wherein the first base layer is made of glass or organic resin, and the second base layer is made of glass or organic resin.
